(19) United States
(12) Patent Application Publication
(10) Pub. No.: US 2019/0027637 A1
(43) Pub. Date: Jan. 24, 2019

(54) SOLAR CELL AND METHOD OF MANUFACTURING SAME

(71) Applicant: Panasonic Intellectual Property Management Co., Ltd., Osaka (JP)

(72) Inventors: Hirotaka Katayama, Osaka (JP); Wataru Shinohara, Fukushima (JP); Keiichiro Masuko, Osaka (JP)

(73) Assignee: Panasonic Intellectual Property Management Co., Lt d., Osaka (JP)

(21) Appl. No.: 16/144,287

(22) Filed: Sep. 27, 2018

Related U.S. Application Data
(63) Continuation of application No. PCT/JP2017/000028, filed on Jan. 4, 2017.

(30) Foreign Application Priority Data
Mar. 28, 2016 (JP) 2016-063028

(51) Int. Cl. H01L 31/18; H01L 31/0216; H01L 31/0224; H01L 31/0747; H01L 31/20

(52) U.S. Cl. CPC H01L 31/1888; H01L 31/02168; H01L 31/202; H01L 31/022466; H01L 31/0747; H01L 31/022425

(57) ABSTRACT

In a backside-junction type solar cell, polycrystalline silicon grains including at least one of amorphous silicon microcrystalline silicon, and polycrystalline silicon exist discretely over a passivation layer and a second conductivity type layer.

### INCORPORATION BY REFERENCE

This application is a U.S. continuation application of PCT International Patent Application Number PCT/JP2017/000028, filed Jan. 4, 2017, claiming the benefit of priority of Japanese Patent Application Number 2016-063028, filed Mar. 28, 2016, the entire contents of which are hereby incorporated by reference.

### TECHNICAL FIELD

The present disclosure relates to a solar cell and a manufacturing method thereof, and in particular to a backside-junction type solar cell and a manufacturing method thereof.

### BACKGROUND

As a solar cell having a high power generation efficiency, there is known a backside-junction type solar cell in which both an n-type semiconductor layer and p-type semiconductor layer are formed over a back surface which opposes a light receiving surface on which light is incident. In the backside-junction type solar cell, there are some cases in which, after a transparent conductive layer is formed over an amorphous silicon layer, the transparent conductive layer is vaporization-machined using a laser, to separate electrodes.

When an electrode separation process for the transparent conductive layer is executed by vaporization using a laser, there had been a possibility that a leakage path is formed in the amorphous silicon layer, which resulted in degradation of characteristics of the solar cell.

The present disclosure has been made in consideration of the above circumstances, and an advantage of the present disclosure lies in provision of a solar cell having a higher power generation efficiency.

### SUMMARY

According to one aspect of the present disclosure, there is provided a solar cell, which is of a backside junction type in which an electrode portion is provided only over one surface of main surfaces of a semiconductor substrate, the solar cell including: a first amorphous silicon layer provided over a side of the one surface of the semiconductor substrate; and the electrode portion provided over the first amorphous silicon layer, wherein the electrode portion includes an n-side electrode which collects electrons and a p-side electrode which collects holes, the n-side electrode and the p-side electrode being separated from each other by a groove, and grains including at least one of amorphous silicon, microcrystalline silicon, and polycrystalline silicon discretely exist in at least one layer of the first amorphous silicon layer provided in a region in which the groove is formed.

According to another aspect of the present disclosure, there is provided a method of manufacturing a solar cell, which is of a backside-junction type in which an electrode portion is provided only over one surface of main surfaces of a semiconductor substrate, the method including: a thin film formation step in which a layered structure of an insulating layer, an amorphous silicon layer formed over the insulating layer, and a transparent conductive layer formed over the amorphous silicon layer is formed over the one surface of the semiconductor substrate; a first laser irradiation step in which a laser including a wavelength band which is absorbed by the transparent conductive layer is irradiated onto the layered structure from above the one surface of the semiconductor substrate, to remove the transparent conductive layer; and a second laser irradiation step in which, after the first laser irradiation step, a laser is again irradiated onto a region in which the transparent conductive layer is removed.

According to various aspects of the present disclosure, formation of the leakage path by the laser machining can be suppressed, and a solar cell having a high power generation efficiency can be provided.

### BRIEF DESCRIPTION OF DRAWINGS

The figures depict one or more implementations in accordance with the present teaching, by way of example only, not by way of limitations. In the figures, like reference numerals refer to the same or similar elements.

FIG. 1 is a plan view showing a solar cell according to an embodiment of the present disclosure.

FIG. 2 is a cross-sectional diagram showing a structure of a solar cell according to an embodiment of the present disclosure.

FIG. 3 is a cross-sectional diagram schematically showing a manufacturing step of a solar cell according to an embodiment of the present disclosure.

FIG. 4 is a cross-sectional diagram schematically showing a manufacturing step of a solar cell according to an embodiment of the present disclosure.

FIG. 5 is a cross-sectional diagram schematically showing a manufacturing step of a solar cell according to an embodiment of the present disclosure.

FIG. 6 is a cross-sectional diagram schematically showing a manufacturing step of a solar cell according to an embodiment of the present disclosure.

FIG. 7 is an enlarged plan view schematically showing a manufacturing step of a solar cell according to an embodiment of the present disclosure.

FIG. 8 is a cross-sectional diagram schematically showing a manufacturing step of a solar cell according to an embodiment of the present disclosure.

FIG. 9 is a cross-sectional diagram schematically showing a manufacturing step of a solar cell according to an embodiment of the present disclosure.

FIG. 10 is a cross-sectional diagram schematically showing a manufacturing step of a solar cell according to an embodiment of the present disclosure.

FIG. 11 is a cross-sectional diagram schematically showing a manufacturing step of a solar cell according to an embodiment of the present disclosure.

FIG. 12 is a cross-sectional diagram schematically showing a manufacturing step of a solar cell according to an embodiment of the present disclosure.

FIG. 13 is a cross-sectional diagram schematically showing a manufacturing step of a solar cell according to an embodiment of the present disclosure.

FIG. 14 is a cross-sectional diagram schematically showing a manufacturing step of a solar cell according to an embodiment of the present disclosure.

FIG. 15 is a cross-sectional schematic diagram of a solar cell over a first insulating layer according to an embodiment of the present disclosure.

FIG. 16 is an SEM observation photograph of a solar cell over a first insulating layer according to an embodiment of the present disclosure.

FIG. 17 is a cross-sectional diagram schematically showing a manufacturing step of a solar cell according to an embodiment of the present disclosure.

FIG. 18 is a cross sectional schematic diagram of a solar cell over a first insulating layer according to an embodiment of the present disclosure.

FIG. 19 is an SEM observation photograph of a solar cell over a first insulating layer according to an embodiment of the present disclosure.

FIG. 20 is an enlarged plan view showing a leakage path in an alternative configuration of the present disclosure.

FIG. 21 is an enlarged plan view showing another example leakage path in an alternative configuration of the present disclosure.

An embodiment of the present disclosure will now be described in detail with reference to the drawings. In the description of the drawings, the same elements are assigned the same reference numerals, and repetitious descriptions thereof will be omitted as suited.

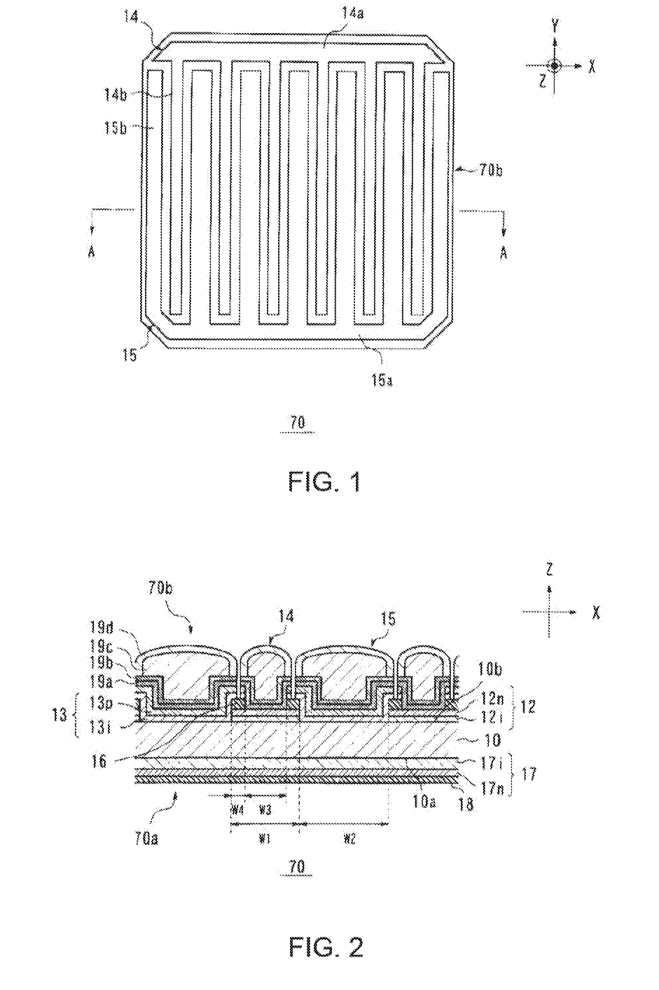

FIG. 1 is a plan view showing a solar cell 70 according to an embodiment of the present disclosure, and shows a structure of a back surface 70b of the solar cell 70.

The solar cell 70 comprises an n-side electrode 14 and a p-side electrode 15 provided over the back surface 70b. The n-side electrode 14 is formed in a comb shape including a bus bar electrode 14a extending in an x direction and a plurality of finger electrodes 14b extending in a y direction. Similarly, the p-side electrode 15 is formed in a comb shape including a bus bar electrode 15a extending in the x direction and a plurality of finger electrodes 15b extending in the y direction. The n-side electrode 14 and the p-side electrode 15 are formed in such a manner that the teeth thereof are interposed between each other. Alternatively, each of the n-side electrode 14 and the p-side electrode 15 may be a bus bar-less type electrode having only the plurality of fingers and no bus bar.

FIG. 2 is a cross-sectional diagram showing a structure of the solar cell 70 according to the present embodiment, and shows a cross section along a line A-A of FIG. 1. The solar cell 70 comprises a semiconductor substrate 10, a first passivation layer 12i, a first conductivity type layer 12n, a second passivation layer 13i, a second conductivity type layer 13p, a first insulating layer 16, a third passivation layer 17i, a third conductivity type layer 17n, a second insulating layer 18, and an electrode layer 19. The electrode layer 19 forms the n-side electrode 14 or the p-side electrode 15. The solar cell 70 is a backside junction type, photovoltaic element in which the first conductivity type layer 12n and the second conductivity type layer 13p are provided on the side of the back surface 70b.

The semiconductor substrate 10 has a first main surface 10a provided on the side of a light receiving surface 70a, and a second main surface 10b provided on the side of the back surface 70b. The semiconductor substrate 10 absorbs light incident on the first main surface 10a, and generates electrons and holes as carriers. The semiconductor substrate 10 is formed from a crystalline semiconductor material having a conductivity type of an n-type or a p-type. The semiconductor substrate 10 in the present embodiment is an n-type monocrystalline silicon wafer.

The light receiving surface 70a refers to a main surface onto which light (solar light) is primarily incident in the solar cell 70, and more specifically refers to a surface onto which most of the light incident on the solar cell 70 is incident. On the other hand, the back surface 70b refers to the other main surface which opposes the light receiving surface 70a.

A first layered structure 12 and a second layered structure 13 are formed over the second main surface 10b of the semiconductor substrate 10. Each of the first layered structure 12 and the second layered structure 13 is formed in a comb shape corresponding to the n-side electrode 14 and the p-side electrode 15, and the layered structures are formed in such a manner as to interpose each other. Because of this, a first region W1 in which the first layered structure 12 is provided and a second region W2 in which the second layered structure 13 is provided are alternately arranged in the x direction over the second main surface 10b. In addition, the first layered structure 12 and the second layered structure 13 adjacent in the x direction are provided in contact with each other. Therefore, in the present embodiment, substantially the entirety of the second main surface 10b is covered by the first layered structure 12 and the second layered structure 13.

The first layered structure 12 is formed from the first passivation layer 12i formed over the second main surface 10b, and the first conductivity type layer 12n formed over the first passivation layer 12i. The first passivation layer 12i is formed from a substantially intrinsic amorphous semiconductor (hereinafter, intrinsic semiconductor will be also referred to as “i-type layer”). In the present embodiment, an “amorphous semiconductor” includes a microcrystalline semiconductor. A microcrystalline semiconductor refers to a semiconductor in which semiconductor crystals are precipitated in the amorphous semiconductor.

The first passivation layer 12i is formed from i-type amorphous silicon including hydrogen (H), and has a thickness of for example, about a few nm˜25 nm. No particular limitation is imposed on a formation method of the first passivation layer 12i, and, for example, the first passivation layer 12i may be formed by chemical vapor deposition (CVD) such as plasma CVD. It is sufficient that the first passivation layer 12i is a thin film which can reduce recombination centers of carriers on the surface of the semiconductor substrate 10, and the first passivation layer 12i may be formed using silicon oxide (SiO₂), silicon nitride (SiN), or silicon oxynitride (SiON).

The first conductivity type layer 12n is formed from an amorphous semiconductor doped with an n-type dopant which is of the same conductivity type as the semiconductor substrate 10. The first conductivity type layer 12n in the present embodiment is formed from n-type amorphous silicon including hydrogen. The first conductivity type layer 12n has, for example, a thickness of about 2 nm 50 nm.

The first insulating layer 16 is formed over the first layered structure 12. The first insulating layer 16 is not provided in a third region W3 corresponding to a central part in the x direction of the first region W1, and is provided in a fourth region W4 corresponding to ends other than the third region W3. A width of the fourth region W4 in which the first insulating layer 16 is formed is, for example, about ⅓ of a width of the first region W1. A width of the third region W3 in which the first insulating layer 16 is not provided is, for example, about ⅓ of the width of the first region W1.

The first insulating layer 16 is formed from, for example, silicon oxide (SiO₂), silicon nitride (SiN), silicon oxynitride (SiON), or the like. The first insulating layer 16 is desirably formed from silicon nitride, and desirably contains hydrogen.

The second layered structure 13 is formed over the second region W2, of the second main surface 10b, in which the first layered structure 12 is not provided, and over an end of the fourth region W4 in which the first insulating layer 16 is provided. Because of this structure, the ends of the second layered structure 13 are provided overlapping the first layered structure 12 in a height direction (z direction).

The second layered structure 13 is formed from the second passivation layer 13i formed over the second main surface 10b, and the second conductivity type layer 13p formed over the second passivation layer 13i. The second passivation layer 13i is formed from i-type amorphous silicon including hydrogen, and has a thickness of, for example, about a few nm˜25 nm. Similar to the first passivation layer 12i, the second passivation layer 13i may be formed using silicon oxide (SiO₂), silicon nitride (SiN), or silicon oxynitride (SiON).

The second conductivity type layer 13p is formed from an amorphous semiconductor doped with a p-type dopant which is of a different conductivity type than the semiconductor substrate 10. The second conductivity type layer 13p in the present embodiment is formed from p-type amorphous silicon including hydrogen. The second conductivity type layer 13p has a thickness of, for example, about 2 m˜50 nm.

Here, the i-type amorphous silicon refers to amorphous silicon having a dopant content of less than 1×10¹⁹ cm⁻³. The n-type amorphous silicon refers to amorphous silicon having an n-type dopant content of greater than or equal to 5×10¹⁹ cm⁻³. Further, the p-type amorphous silicon refers to amorphous silicon having a p-type dopant content of greater than or equal to 5×10¹⁹ cm⁻³.

The n-side electrode 14 which collects the electrons is formed over the first conductivity type layer 12n. The p-side electrode 15 which collects the holes is formed over the second conductivity type layer 13p. A groove is formed between the n-side electrode 14 and the p-side electrode 15, and the electrodes are electrically insulated from each other. In the present embodiment, the n-side electrode 14 and the p-side electrode 15 are formed from a layered structure of four conductive layers including a first conductive layer 19a to a fourth conductive layer 19d, which are insulated by formation of the groove in the fourth region W4.

The first conductive layer 19a is formed from a transparent conductive oxide (TCO) such as, for example, tin oxide (SnO₂), zinc oxide (ZnO), and indium tin oxide (ITO). The first conductive layer 19a in the present embodiment is formed from the indium tin oxide, and has a thickness of, for example, about 50 nm˜100 nm.

The second conductive layer 19b to the fourth conductive layer 19d are made of a conductive material including metals such as copper (Cu), tin (Sn), gold (Au), silver (Ag), or the like. In the present embodiment, the second conductive layer 19b and the third conductive layer 19c are formed from copper, and the fourth conductive layer 19d is formed from tin. The second conductive layer 19b, the third conductive layer 19c, and the fourth conductive layer 19d respectively have thicknesses of about 50 nm˜1000 nm, about 10 μm˜20 μm, and about 1 μm˜5 μm.

No particular limitation is imposed on a formation method of the first conductive layer 19a through the fourth conductive layer 19d, and the conductive layers can be formed, for example, by a thin film formation method such as sputtering and chemical vapor deposition (CVD), or by plating. In the present embodiment, the first conductive layer 19a and the second conductive layer 19b are formed by the thin film formation method, and the third conductive layer 19c and the fourth conductive layer 19d are formed by plating.

The third passivation layer 17i is provided over the first main surface 10a of the semiconductor substrate 10. The third passivation layer 17i is formed from i-type amorphous silicon including hydrogen, and has a thickness of, for example, about a few nm˜25 nm. Similar to the first passivation layer 12i, the third passivation layer 17i may be formed from silicon oxide (SiO₂), silicon nitride (SiN), or silicon oxynitride (SiON).

The third conductivity type layer 17n is provided over the third passivation layer 17i. The third conductivity type layer 17n is formed from an amorphous semiconductor doped with n-type dopant which is of the same conductivity type as the semiconductor substrate 10. The third conductivity type layer 17n in the present embodiment is formed from n-type amorphous silicon including hydrogen, and has a thickness of, for example, about 2 nm˜50 nm.

The second insulating layer 18 which functions as a reflection prevention film and a protective film is provided over the third conductivity type layer 17n. The second insulating layer 18 is formed from, for example, silicon oxide, silicon nitride, silicon oxynitride, or the like. A thickness of the second insulating layer 18 is suitably set according to a reflection prevention characteristic as the reflection prevention film or the like, and is, for example, about 80 nm˜1000 nm.

Alternatively, the layered structure of the third passivation layer 17i, the third conductivity type layer 17n, and the second insulating layer 18 may function as a passivation layer of the semiconductor substrate 10. Further, the third conductivity type layer 17n may be formed from amorphous semiconductor doped with a p-type dopant, or the second insulating layer 18 may be directly layered over the third passivation layer 17i without providing the third conductivity type layer 17n.

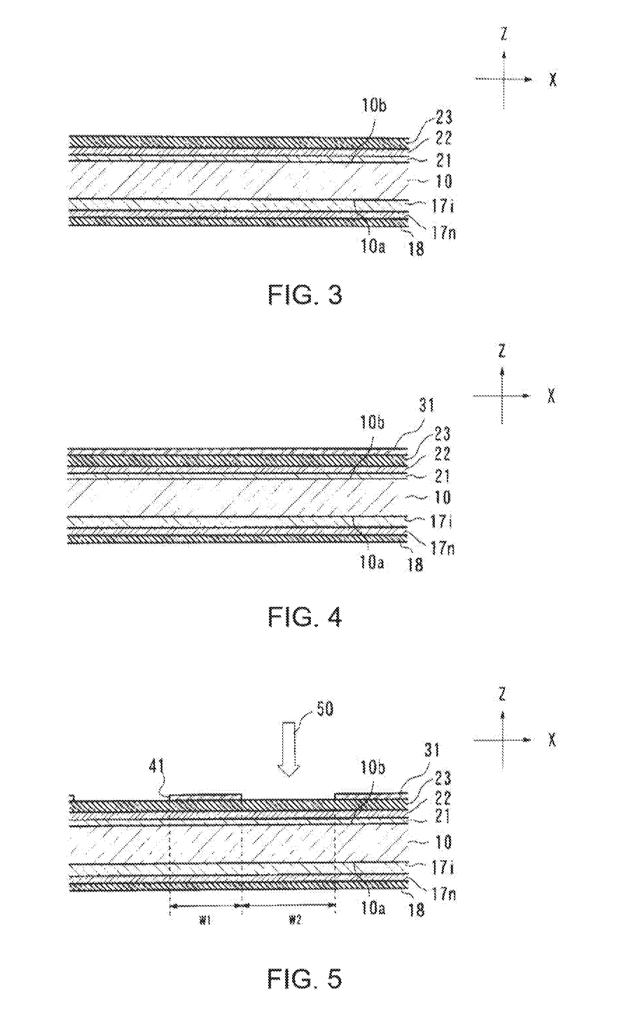

Next, a manufacturing method of the solar cell 70 according to the present embodiment will be described with reference to FIGS. 3-14.

As shown in FIG. 3, an i-type amorphous semiconductor layer 21, an n-type amorphous semiconductor layer 22, and an insulating layer 23 are formed over the second main surface 10b of the semiconductor substrate 10. In addition, the third passivation layer 17i, the third conductivity type layer 17n, and the second insulating layer 18 are formed over the first main surface 10a of the semiconductor substrate 10. No particular limitation is imposed on the formation method of each of the i-type amorphous semiconductor layer 21, the n-type amorphous semiconductor layer 22, the insulating layer 23, the third passivation layer 17i, the third conductivity type layer 17n, and the second insulating layer 18, and these layers may be formed, for example, by chemical vapor deposition (CVD) such as plasma CVD, or sputtering.

An order of formation of the layers over the first main surface 10a and the second main surface 10b of the semiconductor substrate 10 may be suitably set. In the present embodiment, before the processes for forming the i-type amorphous semiconductor layer 21, the n-type amorphous semiconductor layer 22, and the insulating layer 23 over the second main surface 10b, an i-type amorphous semiconductor layer which becomes the third passivation layer 17i, an n-type amorphous semiconductor layer which becomes the third conductivity type layer 17n, and an insulating layer which becomes the second insulating layer 18 are formed over the first main surface 10a.

Next, as shown in FIG. 4, a first mask layer 31 is formed over the insulating layer 23. The first mask layer 31 is a layer which is used as a mask for patterning the i-type amorphous semiconductor layer 21, the n-type amorphous semiconductor layer 22, and the insulating layer 23. The first mask layer 31 is formed from a material which is used for the semiconductor layer and the insulating layer of the solar cell 70, and is formed from a material having a lower alkali resistance property than the insulating layer 23. The insulating layer 23 is formed from a material including silicon such as, for example, amorphous silicon, silicon nitride having a high silicon content, silicon including oxygen, and silicon including carbon (C). The first mask layer 31 is desirably formed using amorphous silicon, and the first mask layer 31 in the present embodiment is formed from an i-type amorphous silicon layer. The first mask layer 31 is formed thin to facilitate removal in a process of laser irradiation shown in FIG. 5 to be described next, and has a thickness of, for example, about 2 nm˜50 nm.

Next, as shown in FIG. 5, a laser 50 is irradiated onto the first mask layer 31, to remove a part of the first mask layer 31. The laser 50 is irradiated onto the second region W2 in which the second layered structure 13 is to be provided, and a first opening 41 is formed in the second region W2, in which the insulating layer 23 is exposed. The laser 50 is irradiated with an intensity to primarily remove only the first mask layer 31, and is irradiated with an intensity to not expose the layers below the insulating layer 23 in the laser irradiated area. In order to suppress multiple reflection due to unevenness of the surface of the first mask layer 31, liquid of a lower index of refraction or a film of a lower index of refraction than the first mask layer 31, such as water and silicon oxide, may be provided over the first mask layer 31, and the laser 50 may then be irradiated.

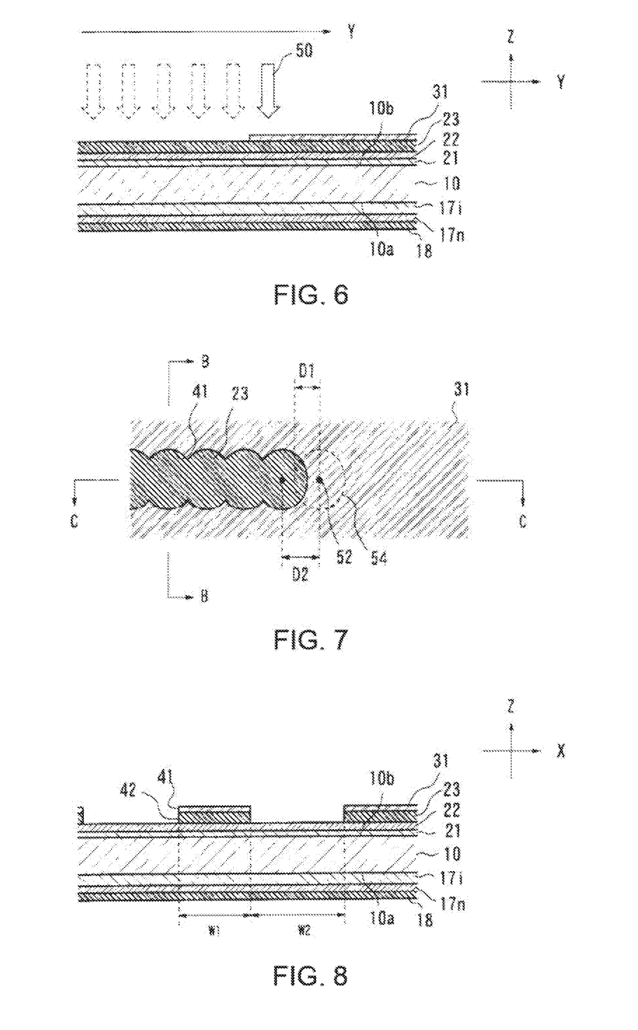

FIGS. 6 and 7 are diagrams showing a process of forming the first opening 41 by the laser 50. FIG. 6 is a cross-sectional diagram orthogonal to the cross section shown in FIG. 5, and FIG. 7 is a plan view, showing the first mask layer 31 from the above. FIG. 5 corresponds to a cross section along a line B-B of FIG. 7, and FIG. 6 corresponds to a cross section along a line C-C of FIG. 7. As shown in FIG. 6, the laser 50 is irradiated while the irradiation position is shifted in the Y direction, and, as shown in FIG. 7, a partial region of the first mask layer 31 is etched to form the first opening 41 extending in a band shape.

The laser 50 is irradiated in such a manner that irradiation ranges 54 of the laser 50 at adjacent irradiation positions partially overlap each other, and is irradiated while the position is shifted such that a center 52 of the laser 50 is not positioned in an area in which the insulating layer 23 is exposed by the laser irradiation. In other words, the laser 50 is desirably irradiated such that a spacing D2 between adjacent laser irradiations is larger than a radius D1 of the irradiation range 54 in which the first mask layer 31 is removed by the irradiation of the laser 50. By employing a configuration in which the irradiation ranges 54 of the laser 50 do not overlap each other, damage to the semiconductor layers below the insulating layer 23 by the laser irradiation is prevented. In the present embodiment, the irradiation ranges 54 of the laser 50 in adjacent irradiation positions are set to partially overlap each other, but alternatively, a configuration may be employed in which the irradiation ranges 54 of the laser 50 in adjacent irradiation positions do not overlap each other. By discretely placing the irradiation ranges 54 of the laser 50, a number of irradiations of the laser 50 can be reduced, and the manufacturing process can be simplified.

The laser 50 is desirably a short-pulse laser having a pulse width of nanoseconds (ns) or picoseconds (ps), in order to reduce the effect of heat on the laser irradiated area. As such a laser 50, a YAG laser, an excimer laser, or the like may be employed. In the present embodiment, as a laser light source, a third harmonic (having a wavelength of 355 nm) of a Nd:YAG laser (having a wavelength of 1064 nm) is used, and the laser 50 is irradiated with an intensity of approximately 0.1˜0.5 J/cm² per pulse. In order to allow formation of the first opening 41 by the laser 50 in a short period of time, desirably, a laser light source having a high repetition frequency is used.

Next, as shown in FIG. 8, using the first mask layer 31 patterned by the laser irradiation, the insulating layer 23 exposed in the first opening 41 is etched. The etching of the insulating layer 23 may be realized using an acidic etching agent such as an aqueous solution of hydrogen fluoride, for example, when the insulating layer 23 is formed from silicon oxide, silicon nitride, or silicon oxynitride. The etching agent used for chemical etching may be liquid or gas. With the etching of the insulating layer 23 positioned in the second region W2, a second opening 42 is formed in which the n-type amorphous semiconductor layer 22 is exposed.

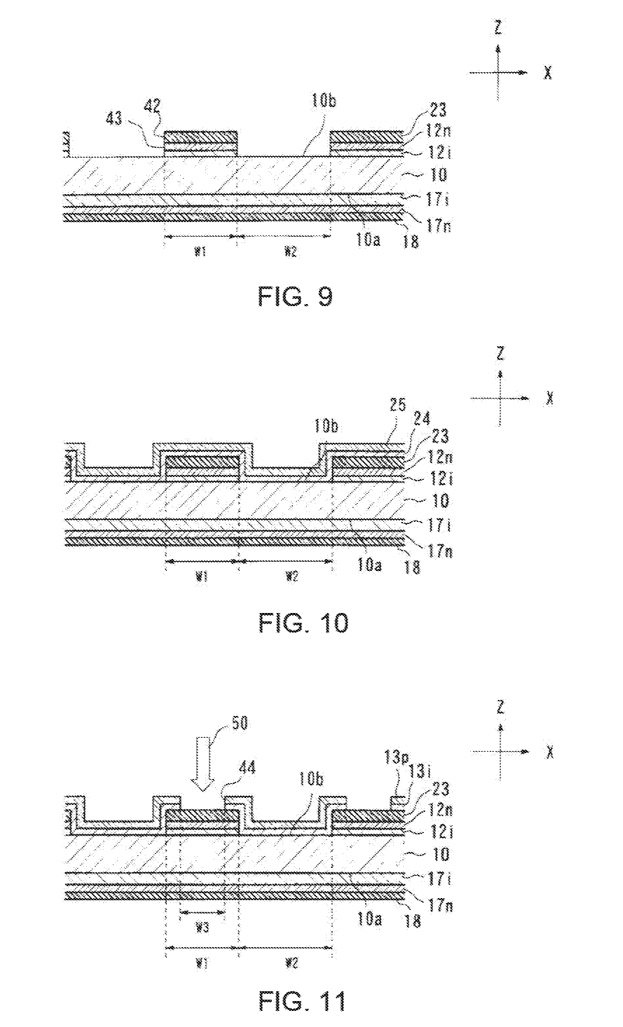

Next, as shown in FIG. 9, using the patterned insulating layer 23 as a mask, the i-type amorphous semiconductor layer 21 and the n-type amorphous semiconductor layer 22 are etched. The i-type amorphous semiconductor layer 21 and the n-type amorphous semiconductor layer 22 can be etched using an alkaline etching agent. By removing the i-type amorphous semiconductor layer 21 and the n-type amorphous semiconductor layer 22 positioned in the second region W2, a third opening 43 is formed in which the second main surface 10b of the semiconductor substrate 10 is exposed. In addition, the first layered structure 12 is formed by the i-type amorphous semiconductor layer 21 and the n-type amorphous semiconductor layer 22 remaining in the first region W1. The first mask layer 31 over the insulating layer 23 is removed in the etching process of the i-type amorphous semiconductor layer 21 and the n-type amorphous semiconductor layer 22 together with these layers. The second opening 42 and the third opening 43 formed after the etching process form an integral groove having the second main surface 10b of the semiconductor substrate 10 as a bottom surface. Alternatively, the first mask layer 31 may be removed by a process separate from the etching of the i-type amorphous semiconductor layer 21 and the n-type amorphous semiconductor layer 22.

Next, as shown in FIG. 10, an i-type amorphous semiconductor layer 24 is formed covering the second main surface 10b and the insulating layer 23, and a p-type amorphous semiconductor layer 25 is formed over the i-type amorphous semiconductor layer 24. No particular limitation is imposed on a formation method of the i-type amorphous semiconductor layer 24 and the p-type amorphous semiconductor layer 25, and, for example, these layers may be formed by a thin film formation method such as CVD. The i-type amorphous semiconductor layer 24 and the p-type amorphous semiconductor layer 25 function as a second mask layer for further patterning the insulating layer 23.

Next, as shown in FIG. 11, the laser 50 is irradiated onto a part of the second mask layer positioned over the insulating layer 23 in the first region W1. In the third region W3 in which the laser 50 is irradiated, a fourth opening 44 is formed in which the insulating layer 23 is exposed. Portions of the second mask layer other than the third region W3 are left by the laser irradiation, the i-type amorphous semiconductor layer 24 becomes the second passivation layer 13i, and the p-type amorphous semiconductor layer 25 becomes the second conductivity type layer 13p. In other words, the second layered structure 13 is formed by the second mask layer.

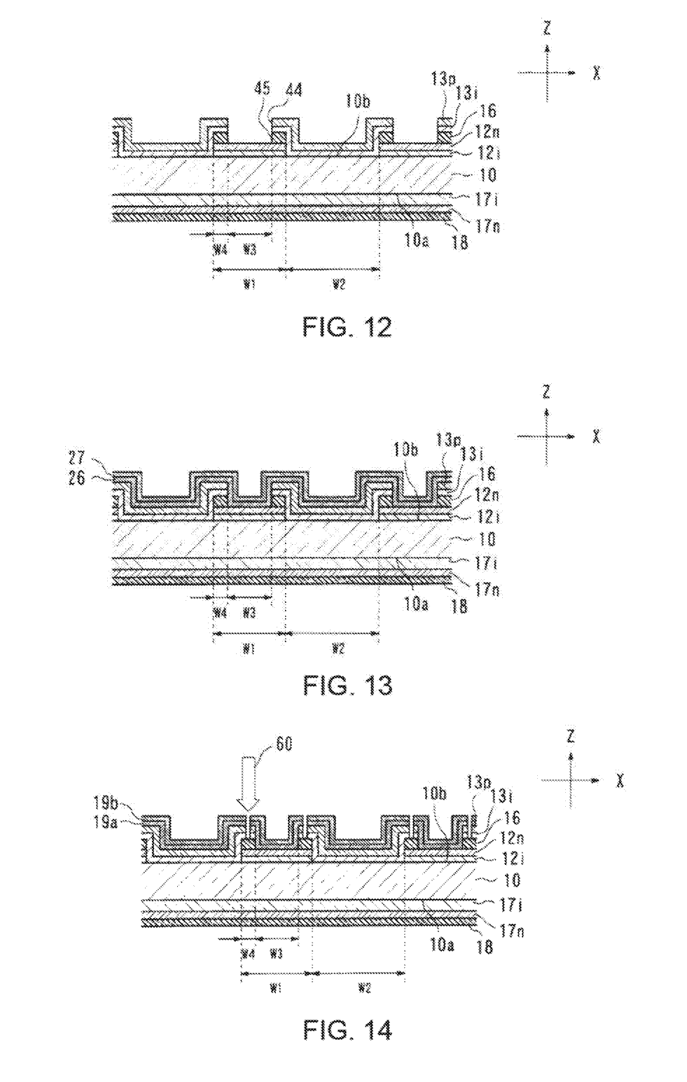

Next, as shown in FIG. 12, the insulating layer 23 exposed in the fourth opening 44 is etched using the second mask layer which is patterned. The insulating layer 23 may be etched using an acidic etching agent such as an aqueous solution of hydrogen fluoride, similar to the process shown in FIG. 8 and described above. With this process, a fifth opening 45 is formed in the insulating layer 23, the first conductivity type layer 12n is exposed, and the first insulating layer 16 is formed from the insulating layer 23. The portion at which the insulating layer 23 is removed becomes the third region W3, and the portion where the first insulating layer 16 remains becomes the fourth region W4. The fourth opening 44 and the fifth opening 45 formed after the etching process form an integral groove having the surface of the first conductivity type layer 12n as a bottom surface.

Next, as shown in FIG. 13, conductive layers 26 and 27 are formed over the first conductivity type layer 12n and the second conductivity type layer 13p. The conductive layer 26 is a transparent electrode layer such as indium tin oxide (ITO), and the conductive layer 27 is a metal electrode layer formed by a metal such as copper (Cu) or an alloy. The conductive layers 26 and 27 are formed by CVD such as plasma CVD or a thin film formation method such as sputtering.

Next, as shown in FIG. 14, of the conductive layers 26 and 27, portions positioned above the first insulating layer 16 is split, to form a groove. With this process, the first conductive layer 19a and the second conductive layer 19b are formed from the conductive layers 26 and 27, and the n-side electrode and the p-side electrode are separated. The splitting of the conductive layers 26 and 27 is realized by irradiating a laser 60.

Before the conductive layer 26 is removed, the conductive layer 27 at a portion positioned above the first insulating layer 16 is removed. When the conductive layer 27 is a metal electrode layer, the conductive layer 27 is desirably removed by wet etching, but alternatively, the conductive layer 27 may be removed using a laser. In the machining of the conductive layer 26 by the laser 60, the laser 60 irradiated from above the one surface is absorbed by the conductive layer 26 which is a transparent conductive layer, and the conductive layer 26, the second passivation layer 13i, and the second conductivity type layer 13p are vaporized and removed by heat generated by the absorption. Therefore, the laser 60 includes a wavelength which is absorbed by the conductive layer 26. For example, when the conductive layer 26 is indium tin oxide (ITO), the laser 60 desirably has an oscillation wavelength of shorter than or equal to 330 nm. In addition, an irradiation energy density of the laser 60 is desirably greater than or equal to 0.08 J/cm² and less than or equal to 0.17 J/cm².

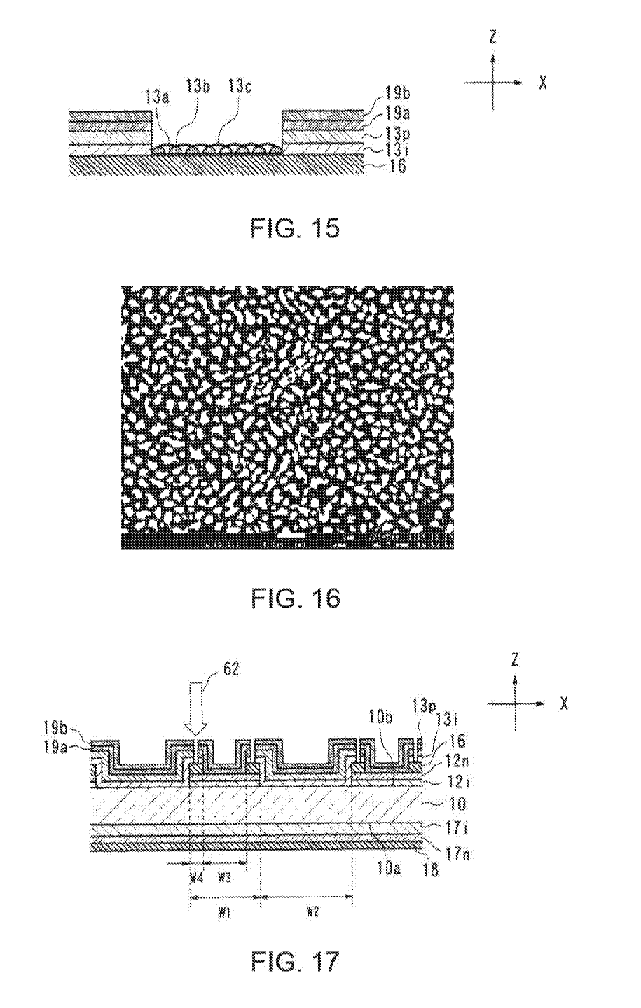

FIG. 15 is a cross-sectional schematic diagram over the first insulating layer 16 after the machining by the laser 60, and FIG. 16 is an electron microscope observation photograph over the first insulating layer 16 after the machining by the laser 60. The second passivation layer 13i and the second conductivity type layer 13p are also simultaneously vaporized by the laser 60, but the amorphous silicon layer 13a remains over the first insulating layer 16. In addition, polycrystalline silicon grains 13b are formed over the amorphous silicon layer 13a, which may be considered to originate from aggregation as crystalline grains after the second passivation layer 13i and the second conductivity type layer 13p are fused. The polycrystalline silicon grains 13b are in a state where an upper part thereof is connected to other nearby polycrystalline silicon grains 13b by a bridge part 13c formed by polycrystalline silicon.

In this manner, by the polycrystalline silicon grains 13b being connected by the bridge part 13c, a conductive (short-circuited) state is realized in a surface direction of the first insulating layer 16. Therefore, if the structure is left in this state, the characteristic of the solar cell 70 may be degraded.

In consideration of this, as shown in FIG. 17, a process is executed in which a laser 62 is further irradiated onto the region in which the conductive layers 26 and 27, the second passivation layer 13i, and the second conductivity type layer 13p are vaporized, to vaporize the bridge part 13c. The laser 62 includes a wavelength which is absorbed by the bridge part 13c. For example, the laser 62 desirably has an oscillation wavelength of shorter than or equal to 330 nm. In addition, an irradiation energy density of the laser 62 is desirably greater than or equal to 0.145 J/cm² and less than or equal to 0.165 J/cm².

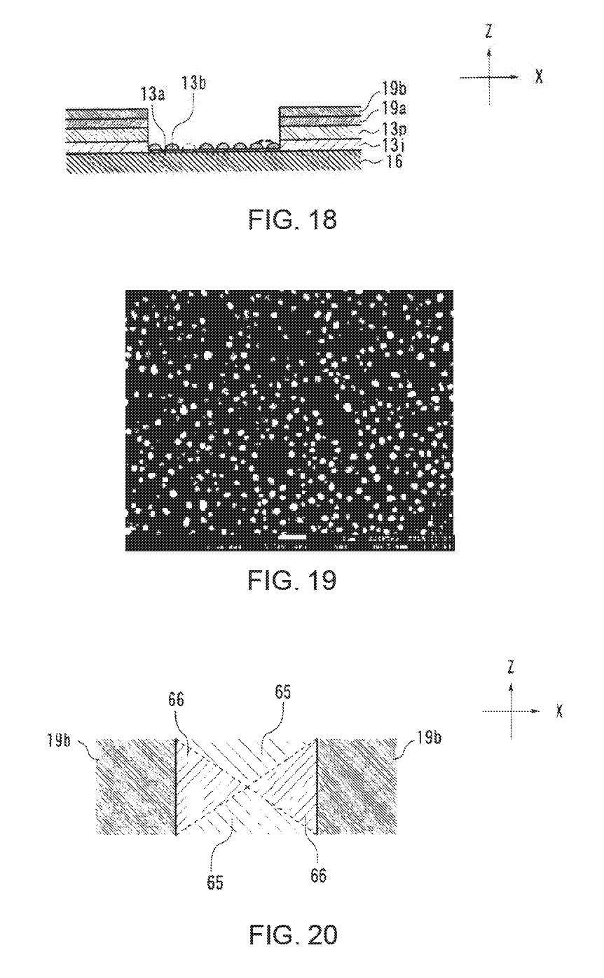

FIG. 18 is a cross-sectional schematic diagram over the first insulating layer 16 after the processing by the laser 62, and FIG. 19 is an electron microscope observation photograph over the first insulating layer 16 after the processing by the laser 62. The bridge part 13c and a part of the polycrystalline silicon grains 13b are vaporized by the laser 62. In this manner, the connection along the surface direction of the first insulating layer 16 by the remaining polycrystalline silicon grains 13b is disconnected, and the polycrystalline silicon grains 13b exist discretely over the first insulating layer 16.

Here, it is desirable to perform the processing such that an average distance between central positions of the remaining polycrystalline silicon grains 13b is larger than a diameter of the polycrystalline silicon grain 13b. With the irradiation conditions of the laser 60 and the laser 62, the diameter of the polycrystalline silicon grain 13b is about 100 nm. Thus, the average distance of the polycrystalline silicon grains 13b is desirably greater than 100 nm, and, for example, the average distance of the polycrystalline silicon grains 13b is set to greater than or equal to 250 nm.

A degree of crystallization of the amorphous silicon layer 13a is higher at the side of the irradiation surface of the laser 62 than the side of the non-irradiation surface, or is approximately constant in the thickness direction. The degree of crystallization may be calculated from a ratio of an intensity of a peak around 520 cm⁻¹ and an intensity of a peak around 470 cm⁻¹ in the Raman spectrum. In addition, a difference in the degree of crystallization can be inspected by a lattice image of a cross-sectional transmissive electron microscope observation (cross-sectional TEM).

Moreover, the compositions of the surface state over the first insulating layer 16 shown in FIG. 19 were checked, and were 11.4 mol % nitrogen (N), 1.2 mol % oxygen (O), and 86.4 mol % silicon (Si), and indium (In) was present in less than or equal to 1 mol %. In other words, in the composition of the surface state over the first insulating layer 16, the composition of silicon (Si) is desirably 70% or more.

With such a process, the characteristic of the solar cell 70 can be improved compared to a case where the further process by the laser 62 after the process by the laser 60 is not applied.

Finally, the third conductive layer 19c including copper (Cu) and the fourth conductive layer 19d including tin (Sn) are formed by plating over the first conductive layer 19a and the second conductive layer 19b. The third conductive layer 19c and the fourth conductive layer 19d are formed by plating, through a process of setting the first conductive layer 19a and the second conductive layer 19b as seed layers, and applying a current. With the manufacturing process described above, the solar cell 70 as shown in FIG. 2 is completed.

According to the present embodiment, the electrical shorting (short-circuiting) at an interface between the polycrystalline silicon grain 13b and the bridge part 13c can be suppressed, and the characteristic of the solar cell 70 can be improved.

### Alternative Configuration

In the embodiment described above, the process by the laser 62 is applied to the entirety of the region in which the conductive layers 26 and 27, the second passivation layer 13i, and the second conductivity type layer 13p are vaporized. Alternatively, the connection state by the polycrystalline silicon grains 13b and the bridge part 13c may be taken advantage of.

Specifically, in the solar cell 70, a hot spot phenomenon may occur in which, when a part of the surface of the solar cell 70 is set in shadow for some reason, heat is generated in the shadow portion, and the shadow portion is damaged. As a countermeasure for the hot spot, a method is employed in which a bypass diode is provided between the n-side electrode 14 and the p-side electrode 15, of the solar cell 70, which are adjacent to each other, to bypass an excessive current in the hot spot region.

For this purpose, a leakage route (leakage path) of a current may be formed between the n-side electrode 14 and the p-side electrode 15 which are adjacent to each other, using the polycrystalline silicon grain 13b and the bridge part 13c, and the current may flow through the leakage path when the hot spot phenomenon occurs.

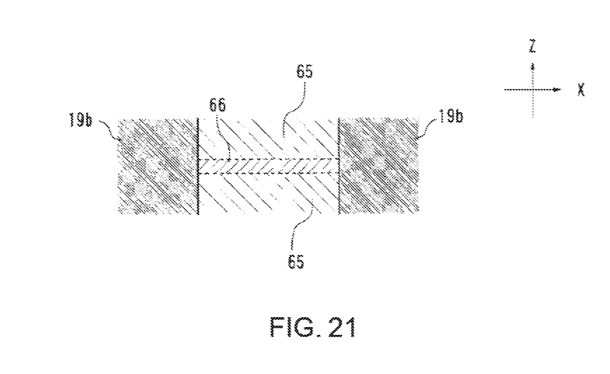

For example, as shown in a surface enlarged view over the first insulating layer 16 of FIG. 20, a region 65 in which the laser 62 is irradiated and a region 66 in which the laser 62 is not irradiated are provided, and a suitable leakage path is formed by the non-irradiated region 66, between the n-side electrode 14 and the p-side electrode 15. No particular limitation is imposed on the shape of the leakage path, and the leakage path may have a shape in which vertices of two regions 66 contact each other as shown in FIG. 20, or a shape including regions 66 of a uniform width as shown in FIG. 21. In addition, a plurality of leakage paths are desirably formed as shown in FIG. 21, and repetitious arrangement of a region in which the leakage path is formed and a region in which the leakage path is not formed is desirable.

By providing the leakage path taking advantage of the connection state by the polycrystalline silicon grains 13b and the bridge part 13c, it becomes possible to prevent damages of the solar cell 70 due to the hot spot.

The present disclosure has been described with reference to the embodiment and the alternative configuration. The present disclosure, however, is not limited to the embodiment and the alternative configuration, and the structures of the embodiment and the alternative configuration may be suitably combined or substituted.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell, which is of a backside junction type in which an electrode portion is provided only over one surface of main surfaces of a semiconductor substrate, the solar cell comprising:
a first amorphous silicon layer provided over a side of the one surface of the semiconductor substrate; and
the electrode portion provided over the first amorphous silicon layer, wherein
the electrode portion comprises an n-side electrode which collects electrons and a p-side electrode which collects holes, the n-side electrode and the p-side electrode being separated from each other by a groove, and
grains including at least one of amorphous silicon, microcrystalline silicon, and polycrystalline silicon discretely exist in at least one layer of the first amorphous silicon layer provided in a region in which the groove is formed.

2. The solar cell according to claim 1, wherein
the grains exist discretely over the first amorphous silicon layer.

3. The solar cell according to claim 2, further comprising:
an insulating layer provided between the semiconductor substrate and the first amorphous silicon layer, in a region in which the groove is formed.

4. The solar cell according to claim 3 farther comprising:
a second amorphous silicon layer provided between the semiconductor substrate and the insulating layer, and having a different conductivity type than that of the first amorphous silicon layer, wherein
the n-side electrode is formed over one of the first amorphous silicon layer and the second amorphous silicon layer and collects the electrons, and
the p-side electrode is formed over the other of the first amorphous silicon layer and the second amorphous silicon layer, and collects the holes.

5. The solar cell according to claim 2, wherein
the grains have an average distance between centers of greater than or equal to 250 nm.

6. The solar cell according to claim 2, wherein
an average distance between centers of the grains is greater than a diameter of the grains.

7. The solar cell according to claim 1, wherein
the grains exist non-uniformly over the amorphous silicon layer.

8. A method of manufacturing a solar cell, which is of a backside junction type in which an electrode portion is provided only over one surface of main surfaces of a semiconductor substrate, the method comprising:
a thin film formation step in which a layered structure of an insulating layer, an amorphous silicon layer formed over the insulating layer, and a transparent conductive layer formed over the amorphous silicon layer, is formed over the one surface of the semiconductor substrate;
a first laser irradiation step in which a laser including a wavelength band which is absorbed by the transparent conductive layer is irradiated onto the layered structure from above the one surface of the semiconductor substrate, to remove the transparent conductive layer; and
a second laser irradiation step in which, after the first laser irradiation step, a laser is again irradiated onto a region in which the transparent conductive layer is removed.

9. The method of manufacturing the solar cell according to claim 8, further comprising:
a plating step in which, after the second laser irradiation step, a conductive layer including a metal is formed over the transparent conductive layer by plating.

10. The method of manufacturing the solar cell according to claim 9, wherein
the laser used in the first laser irradiation step includes a wavelength of shorter than or equal to 330 nm.

11. The method of manufacturing the solar cell according to claim 10, wherein
the laser used in the second laser irradiation step is irradiated with an energy density of greater than or equal to 0.145 J/cm² and lower than or equal to 0.165 J/cm².
